(19) United States
(12) Patent Application Publication
(10) Pub. No.: US 2005/0067674 A1
(43) Pub. Date: Mar. 31, 2005

(54) Integrated tuneable capacitance

(76) Inventor: Judith Maget, Taufkirchen (DE)

Correspondence Address: ESCHWEILER & ASSOCIATES, LLC;NATIONAL CITY BANK BUILDING, 629 EUCLID AVE., SUITE 1210, CLEVELAND, OH, 44114, US

(21) Appl. No.: 10/917,943

(22) Filed: Aug. 13, 2004

Related U.S. Application Data
(63) Continuation of application No. PCT/DE03/00185, filed on Jan. 23, 2003.

(30) Foreign Application Priority Data
Feb. 15, 2002 (DE) DE 102 06 375.3

(51) Int. Cl. H01L 29/94; H01L 21/20

(52) U.S. Cl. 257/595; 438/379; 257/596; 257/598

(57) ABSTRACT

An integrated, tuneable capacitance is disclosed that is based on an MOS transistor. In order to improve the linearity characteristics of the tuning characteristic of the varactor, the invention provides for part of the gate region to be doped with the conductance type p, and part to be doped with the conductance type n. Provision is also made for the gate and source/drain regions not to overlap one another, but to be separated from one another on a horizontal plane. This results in a wider variation ratio with a lower series resistance.

### REFERENCE TO RELATED APPLICATIONS

This application is a continuation of PCT/DE03/00185, which was not published in English, that claims the benefit of the priority date of German Patent Application No. 10206375.3, filed on Feb. 15, 2002, the contents of which both are herein incorporated by reference in their entirety.

### FIELD OF THE INVENTION

The present invention relates to an integrated, tuneable capacitance.

### BACKGROUND OF THE INVENTION

Tuneable capacitances in the present sense are also referred to as varactors or as capacitance diodes. Components such as these are based on the functional principle that the depletion layer capacitance of a diode or the space charge zone in the case of a metal oxide semiconductor (MOS) structure is dependent on the applied DC voltage.

Tuneable capacitances are used, for example, in voltage controlled LC oscillators, in which an LC resonant circuit is provided, which normally comprises a fixed-value inductance as well as a capacitance with a variable capacitance value. The capacitance value can be adjusted by supplying a variable trimming voltage, thus, overall, making it possible to tune the oscillation frequency of the oscillator.

In order to allow as wide a frequency range as possible to be covered, it is desirable to be able to use tuneable capacitances with a wide tuning range. For this purpose, the tuneable capacitances require as high a variation ratio as possible, with this ratio being defined as the quotient of the largest capacitance which can be set divided by the smallest capacitance which can be set.

It is also desirable for such tuneable capacitances to have a low series resistance, thus increasing the achievable Q factor. Furthermore, it is desirable for components such as these to have good linearity. This has good influence on the phase noise of a voltage controlled oscillator.

The document by J Kucera, “Wideband BiCMOS VCO for GSM/UMTS Direct Conversion Receivers”, Proceedings of the 2001 ISSCC, New York, February 2001, specifies a capacitance diode which is produced using bipolar or BiCMOS processes, but which requires more process steps than the more cost-effective production using CMOS.

In the document by P. Andreani, “On the use of MOS varactors in RF VCOs IEEE JSSC Vol. 35, No. 6, pp. 905-910, June 2000, MOS transistors can be used as capacitance diodes by using the existing source/drain junction diodes in CMOS processes. Alternatively, the gate qapacitance of the MOS transistors is used as a tuneable capacitance.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

According to the invention, a tuneable capacitance comprises a semiconductor body, wherein at least one source/drain region which is arranged in the semiconductor body. The tuneable capacitance further comprises a layer stack that is arranged on the semiconductor body that includes an insulating layer and a gate region arranged on the insulating layer. The layer stack further includes a first subregion of a first conductance type, and a second subregion of a second conductance type.

The specified integrated, tuneable capacitance is based on the principle of the gate region being formed partially with a first conductance type and partially with a second conductance type. This is associated with the advantage that the integrated tuneable capacitance can be designed in the same way as a conventional MOS transistor.

The use of the opposite dopant type in respective subareas of the gate region results in the additional advantage that the profile of the capacitance as a function of the voltage is more uniform, and the linearity of the varactor is improved.

In the case of MOS varactors, the improvement in the linearity characteristics on the basis of the present principle is due to the fact that the transition voltage at which a transition takes place from charge carrier depletion to inversion or accumulation is linked to the flatband voltage, and is in a narrow voltage range.

Two source/drain regions are preferably arranged in the semiconductor body.

If the gate region and the region underneath the gate, that is to say between the two source/drain regions in the semiconductor body, are of the same dopant type, then the flatband voltage and hence the transition voltage to accumulation occur at about 0 volts. With the opposite dopant type between the gate region and the region underneath the gate in the semiconductor body between the source/drain regions, the flatband voltage and the transition voltage to accumulation occur at a magnitude of about 1 volt. The threshold voltage, that is to say the transition voltage to inversion of the charge carriers, is shifted in a corresponding manner.

The superimposition of the stepped characteristic profiles which are produced by these two effects results in a considerable improvement to the linearity of varactors according to the invention.

The materials which are normally provided as the gate region in MOS technology, such as polycrystalline silicon, which is also referred to as polysilicon, are normally doped in any case in order to produce sufficiently good conductivity, so that the effort required to produce the tuneable capacitance of the present invention is extremely low.

Gate subregions of a different conductance type are preferably arranged alongside one another, rather than one above the other, on the semiconductor body.

According to one preferred embodiment of the invention, the integrated, tuneable capacitance has a finger structure with at least two gate subregions, which are arranged parallel and extend in a preferred direction, one of which is in the form of a first subregion of the first conductance type, and another of which is in the form of a second subregion of the second conductance type.

The gate region of the varactor is preferably split in this way into two subregions of a different conductance type such that, in an embodiment of the varactor in a finger structure, individual transistor fingers or varactor fingers each have differently doped gate paths.

Transistors and varactors for radio-frequency applications are normally designed using a finger structure, that is to say two or more elongated individual transistors or individual varactors, which are arranged parallel to one another, are electrically connected in parallel. In this case, mutually associated gate regions and mutually associated source/drain regions are electrically connected to one another.

The gate subregions which are arranged parallel to one another and are each associated with source/drain paths which likewise preferably run parallel are preferably doped such that adjacent gate subregions or fingers are of a different conductance type. For example, the first, third, fifth etc gate paths are p-doped, and the second, fourth, sixth etc gate paths are n-doped.

The gate region and the gate subregions which are surrounded by the gate region are preferably in the form of a polycrystalline silicon layer, which is also referred to as polysilicon. A polysilicon gate region such as this, which is also referred to as a poly gate, is normally doped in advance with one conductance type in any case, in order to achieve a gate electrode with sufficiently good conductivity. The previously known standard doping of all gate paths of all the transistor fingers of the same conductance type is, on the basis of the present principle, replaced by the gate region being split into subregions of the first conductance type and subregions of the second conductance type.

The boundary surfaces between n-doped and p-doped gate subregions, that is to say between gate subregions of a different conductance type, are preferably arranged in the connecting webs which electrically connect the individual gate electrode paths to one another, and preferably run at right angles to them.

According to one preferred development of the present invention, well regions, which are of the first conductance type or of the second conductance type, are provided in the semiconductor body, underneath the layer stack and between the source/drain regions.

An electrically insulating region is preferably in each case arranged between the well region underneath the layer stack, that is to say underneath the gate electrode, and between the two source/drain regions, and arranged adjacent to the gate region or partially underneath the gate region.

Insulating regions such as these, which are preferably in the form of so-called shallow trench isolation (STI) regions, advantageously result in an additional increase in the variation ratio while further reducing parasitic capacitances.

According to one preferred development of the present subject matter, the distance between the gate region and the source/drain region or regions on a projection plane parallel to the main face of the semiconductor body is greater than zero.

According to the described development, a distance other than zero is provided between the gate electrode and the source/drain regions of the MOS structure on a projection plane parallel to the main face of the semiconductor body. The direct coupling between the gate electrode and the source/drain regions is thus cancelled, and the source region and drain region are arranged at a distance which can be predetermined from the gate region in the semiconductor body.

A doped well region, which extends to the main face of the semiconductor body, is preferably provided between the two source/drain regions and underneath the layer stack.

In this advantageous development, parasitic overlapping capacitances are avoided, and edge capacitances are reduced. This leads to an increase in the variation ratio, that is to say the ratio of the maximum to the minimum capacitance which can be set.

The described, tuneable capacitance can advantageously be produced by the process steps which are provided in standard CMOS manufacturing processes.

The conductance type of the source/drain regions is advantageously the same as the conductance type of a well region that is arranged between the source/drain regions. In this case, the dopant concentration of the source/drain regions is preferably greater than the dopant concentration of the well region.

The gate region in the layer stack is preferably in the form of a polycrystalline silicon layer. Polycrystalline silicon is also referred to as polysilicon.

In all of the described tuneable capacitances, the source/drain regions are preferably electrically connected to one another.

The source/drain regions, which are electrically connected to one another, are preferably connected to a control input for supplying a control voltage by means of which the capacitance value of the present tuneable capacitance is set. The gate region, that is to say the gate electrode, is preferably designed for the application of a radio-frequency signal.

The described tuneable capacitance can thus advantageously be operated as a varactor in LC oscillators.

### BRIEF DESCRIPTION OF THE DRAWINGS

The invention will be explained in more detail in the following text using a number of exemplary embodiments and with reference to the drawings, in which:

FIG. 1 is a plan view illustrating an example of an integrated tuneable capacitance with a finger structure,

FIG. 2 is a cross section through an example of an integrated tuneable capacitance as shown in FIG. 1,

FIG. 3 is a graph illustrating the profile of a family of characteristics for a varactor according to the prior art with an n-doped poly gate, and an n-well under the gate,

FIG. 4 is the same graph as that in FIG. 3, but for a varactor with a p-doped poly gate and an n-well under the gate,

FIG. 5 is a graph illustrating a family of tuning characteristics for a varactor according to the invention with an n-well under the gate as shown in FIGS. 1 and 2,

FIG. 6 is a cross section through an example of a varactor whose gate and source/drain regions are separated, and

FIG. 7 is a cross section illustrating the same or similar subject matter as FIG. 6, showing concentrated elements.

### DETAILED DESCRIPTION OF THE INVENTION

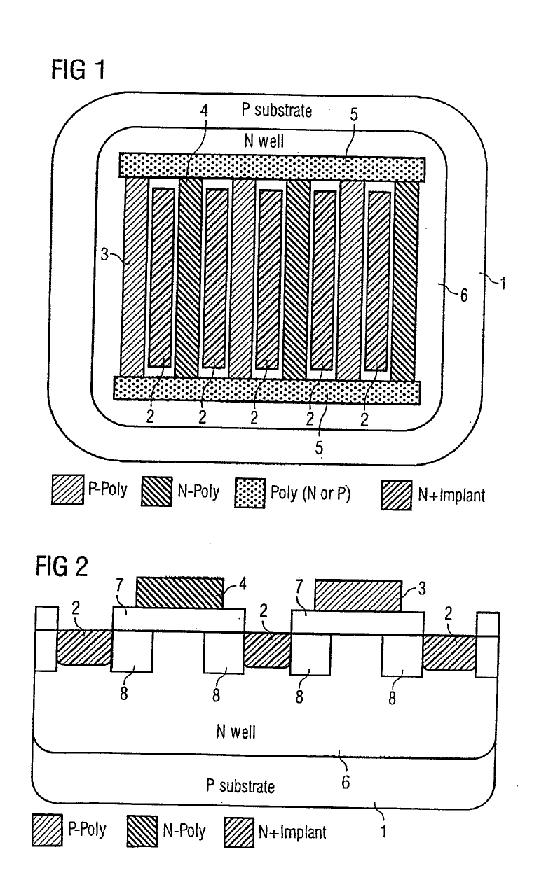

FIG. 1 shows an integrated tuneable capacitance with a semiconductor body which is in the form of a substrate and is doped in advance with the conductance type p. A well 6 of the n conductance type is introduced into the semiconductor body 1 underneath the gate region 3, 4. The well is in this case formed with a dopant concentration n+. Two or more source/drain regions 2, which extend in a preferred direction and are arranged parallel to one another, are introduced as implantation regions into the semiconductor body 1, to be more precise into the n-well 6. These source/drain regions 2 are of the n+ conductance type and have a very much higher dopant concentration than the substrate 1. Gate regions 3, 4 are arranged between the source/drain regions 2, extend parallel to the source/drain regions and likewise extend in the preferred direction, and are alternately of the p conductance type and of the n conductance type. The described p-doped gate subregions 3 and the n-doped gate subregions 4 make contact, in the form of a comb-like structure, with connecting regions 5 which are arranged at right angles to them and are doped with the p or n conductance type. The dopant concentration of the source/drain regions 2 is considerably higher than the dopant concentration of the well region 6.

The arrangement shown in FIG. 1 is based on an MOS varactor of the accumulation type with shallow trench isolation (STI) regions in order to reduce parasitic capacitances, although this has been developed such that the gate regions 3, 4 are alternately n+ and p+ doped with a finger structure. In consequence, the capacitance changes resulting from gate voltage changes and having a step caused by the transition voltage do not occur, with the steps based on the n-polysilicon gate and p-polysilicon gate instead being superimposed so as to considerably improve the linearity of the varactor.

The transition voltage at which the transition takes place from depletion to inversion or accumulation is located in a comparatively narrow voltage range and depends directly on the flatband voltage. If the gate subregion 4 and the well region 6 are of the same conductance type, then the flatband voltage and hence the transition voltage to accumulation occur at about 0 volts while, with opposite doping between the gate subregion 3 and the well region 6, the flatband voltage and the transition voltage to accumulation occur at a magnitude of about 1 volt. The threshold voltage is shifted analogously to this. The described subject matter can be implemented on the basis of all varactors which are based on an MOS structure.

FIG. 2 shows a cross section through a varactor according to the invention based on the present principle with a semiconductor body 1, which is in the form of a p substrate, an n-well 6 embedded in it, and source/drain regions 2 that are implanted in the n-well 6 and run parallel to one another. Two source/drain regions 2 which run parallel to one another are arranged in each gate region 3, 4, which are arranged parallel to the source/drain regions 2 and above the semiconductor body 1 in a layer stack 3, 7; 4, 7. An insulating layer 7 is in each case provided between the semiconductor body 1 or the n-well 6 which is embedded in it and the gate electrodes 3, 4 in the layer stack. The n well 6 extends as far as the isolating region 7 underneath the layer stack 3, 7; 4, 7 and between the source/drain regions 2. A further isolating region 8 is in each case provided between the n-well 6 and the source/drain regions 2, is adjacent not only to the source/drain regions 2 but also to the isolating regions 7, and is in the form of a shallow trench isolation (STI) region.

In the case of the subject matter illustrated in FIGS. 1 and 2, the source/drain regions 2 are connected to one another and form the tuning input of the varactor. The radio-frequency connection of the varactor is formed by the gate regions 3, 4, which are likewise electrically connected to one another.

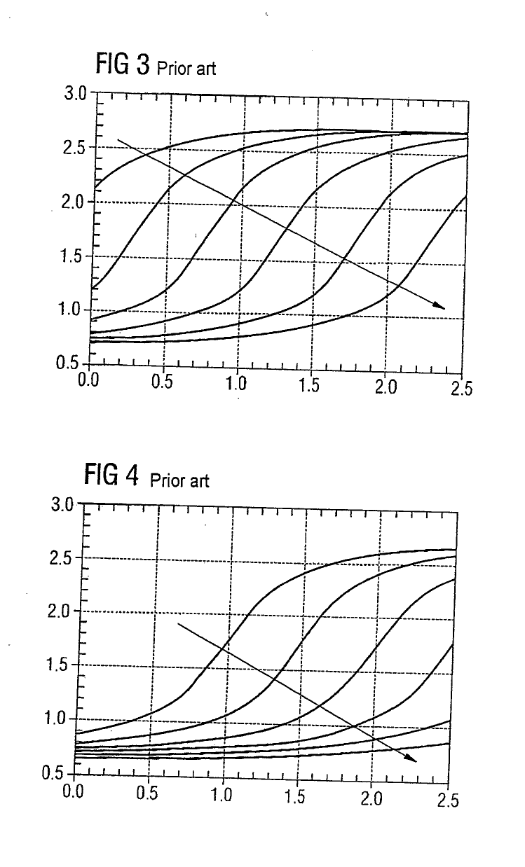

FIG. 3 shows a family of tuning characteristics for a conventional varactor with a polysilicon region as the gate electrode, which is only n-doped. In this case, the capacitance is plotted in picofarads against the gate voltage in volts. The tuning voltage is shown as a family parameter which increases in steps of 0.5 V from 0 V to 2.5 V in the direction of the arrow. As can be seen, the transition from depletion to accumulation involves a voltage step in a relatively narrow voltage range of the described capacitance profile, and thus has a relatively non-linear profile.

The subject matter illustrated in FIG. 4, which likewise shows a graph of a family of tuning characteristics, for a conventional varactor with only a p-doped polysilicon region as the gate electrode, specifically with the varactor capacitance being plotted in picofarads against the gate voltage in volts, with the family parameter of the tuning voltage increasing in 0.5 volts steps from 0 to 2.5 V in the direction of the arrow, has an analogous behaviour to this. In this case as well, each characteristic in the family of curves has a not very linear profile with a step resulting from the described characteristics.

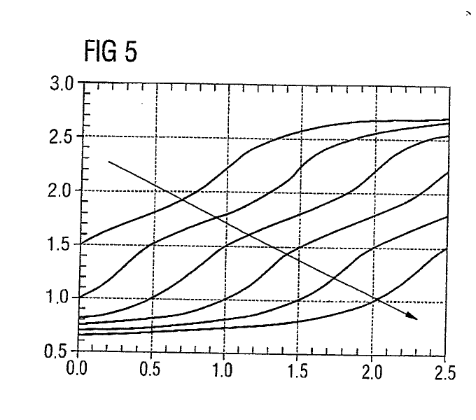

FIG. 5 shows the profile of the tuning family of characteristics for the varactor capacitance of the present invention in picofarads, plotted against the gate voltage, on the basis of a family of curves, with the tuning voltage being varied in 0.5 volt steps from 0 to 2.5 V. The relevant varactor is designed with a finger structure and comprises alternately arranged n+ and p+-doped gate fingers. As can be seen, capacitance changes resulting from gate voltage changes occur in two steps rather than in one step, as in FIGS. 3 and 4. Overall, this considerably improves the linearity of the tuning characteristic of the varactor.

The graphs shown in FIGS. 3 to 5 relate to an accumulation MOS varactor in an n-well.

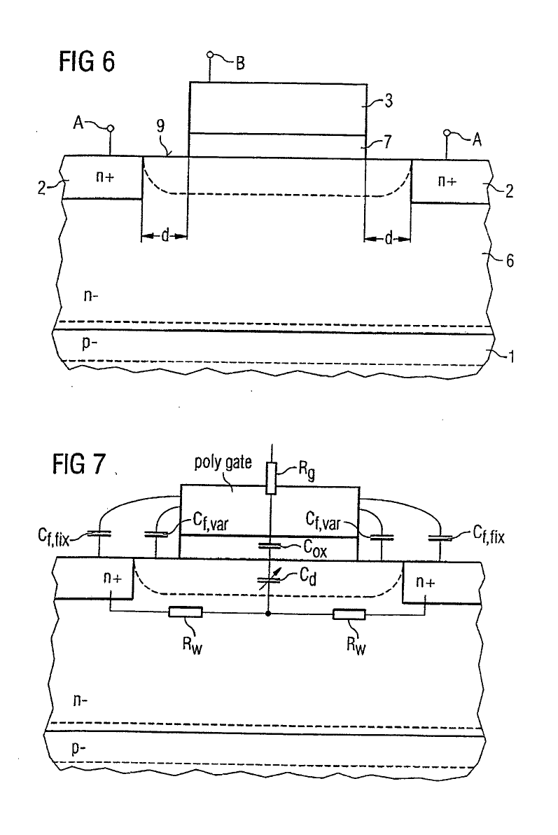

FIG. 6 shows an integrated tuneable capacitance on the basis of a simplified cross section in a detail of the plan view shown in FIG. 1 with the weakly already doped semiconductor body 1, which is in the form of a p-substrate, into which a lightly already doped n-well region 6 of the opposite conductance type is introduced. Two n+ doped source/drain implantation regions 2 are introduced adjacent to a main face 9 of the semiconductor body 1. A layer stack 3, 7 is applied on the main face 9 of the semiconductor body 1 between these source/drain regions 2, comprising an isolating region 7 and a gate polysilicon region 3 applied above it. The two source/drain regions 2 are electrically connected to one another and form the tuning input A of the varactor. The radio-frequency connection B of the varactor is connected to the gate region 3.

In contrast to conventional MOS transistors, when the structure of the present invention is on a projection plane which is arranged parallel to the main face 9 of the semiconductor body 1, the source/drain regions 2 are separated from the gate region 3, with this separation distance being denoted d. In the present exemplary embodiment, the separation distances d are of the same magnitude, although this need not necessarily be the case. This separation between the gate region 3 and the source/drain regions 2 via the separation distance d leads, on the basis of the present principle, to cancellation of the direct coupling between the gate electrode 3 and the source/drain implantation regions 2. In fact, the n-doped well region 6 is located in between, as far as the surface 9. This avoids parasitic overlapping capacitances between the gate electrode 3 and the source/drain region 2, and additionally reduces edge capacitances. This leads to a considerable increase in the variation ratio of the present varactor in addition to the linearization of the tuning characteristic that is inherent with the present principle.

In order to explain the reduction in the parasitic capacitances, the most important resistance elements and capacitance elements involved are shown as concentrated elements in the next figure, FIG. 7, the design and method of operation, whose subject matters correspond to those in FIG. 6. The variation ratio Cmax/Cmin can be stated to be:

$$\frac{{C}_{max}}{{C}_{min}} = \frac{{C}_{max , variable} + {C}_{parasitic}}{{C}_{min , variable} + {C}_{parasitic}}$$

The variable capacitance elements are produced by the oxide capacitance Cox, that is to say the capacitance of the isolating layer 7, and the diffusion capacitance Cd connected in series.

The maximum capacitance cmax,variable which can be set thus results from the oxide capacitance Cox, while the minimum capacitance Cmin, variable which can be set results from the oxide capacitance Cox, that is to say the capacitance of the isolating layer 7, connected in series with the minimum diffusion capacitance Cd.

As can clearly be seen, the reduction in the edge capacitances as well as the absence of the direct capacitances between the source/drain regions and the gate electrode allows a significant increase in the variation ratio in addition to the linearization of the characteristic as described above. This in turn makes it possible to achieve a wider tuning frequency range in LC oscillators in which varactors based on the present principle are used as tuneable elements.

Although the invention has been shown and described with respect to a certain aspect or various aspects, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several aspects of the invention, such feature may be combined with one or more other features of the other aspects as may be desired and advantageous for any given or particular application. Furthermore, to the extent that the term “includes” is used in either the detailed description or the claims, such term is intended to be inclusive in a manner similar to the term “comprising.”

1. An integrated, tuneable capacitance, comprising:
a semiconductor body;
at least one source/drain region arranged in the semiconductor body; and
a layer stack arranged on the semiconductor body, the layer stack comprising an insulating layer and a gate region that is arranged on the insulating layer, wherein the gate region is associated with the at least one source/drain region and comprises a first subregion of a first conductance type, and a second subregion of a second, different conductance type, wherein a distance between the gate region and the at least one source/drain region associated therewith in a projection plane parallel to a main face of the semiconductor body is greater than zero.

2. The capacitance as claimed in claim 1, wherein the integrated, tuneable capacitance comprises a finger structure with at least two gate subregions that are arranged together in parallel and extend in a preferred direction, wherein one of the gate subregions comprises the first conductance type, and the other one of the gate subregions comprises the second, different conductance type.

3. The capacitance as claimed in claim 2, wherein adjacent gate subregions that are arranged together in parallel and extend in the preferred direction each have a different conductance type with respect to one another.

4. The capacitance as claimed in claim 1, wherein the gate region comprises a polycrystalline silicon layer.

5. The capacitance as claimed in claim 1, further comprising another source/drain region arranged in the semiconductor body.

6. The capacitance as claimed in claim 5, further comprising a well region that is of the first or of the second conductance type provided underneath the layer stack in the semiconductor body surrounding the source/drain regions.

7. The capacitance as claimed in claim 5, further comprising an electrically insulating region arranged in the semiconductor body adjacent to or at least partially underneath the gate region, and adjacent to the source/drain regions.

8. The capacitance as claimed in claim 1, wherein the at least one source/drain region comprises two source/drain regions of a first conductance type and a first dopant concentration, further comprising a well region provided in the semiconductor body underneath the gate region and between the two source/drain regions, wherein the well region comprises the first conductance type and has a second dopant concentration that is lower than the first dopant concentration.

9. The capacitance as claimed in claim 8, wherein the gate region comprises a polycrystalline silicon layer.

10. The capacitance as claimed in claim 1, wherein the at least one source/drain region comprises two source/drain regions that are electrically connected to one another and to a circuit node.

11. The capacitance as claimed in claim 10, wherein the circuit node to which the two source/drain regions are connected comprises a control input for supplying a control voltage in order to control a capacitance value of the tuneable capacitance, and wherein the gate region is connected to a connection configured for application of a radio-frequency signal thereto.

12. An integrated, tuneable capacitance, comprising:
a semiconductor body comprising a first conductivity type;
a plurality of source/drain regions in the semiconductor body extending generally parallel to one another along a first direction, the source/drain regions comprising the first conductivity type and spaced apart from each other by a first distance;
a plurality of doped layer stacks overlying the semiconductor body extending generally parallel to one another along the first direction and laterally disposed between the source/drain regions, wherein a width of the layer stacks comprises a second distance that is less than the first distance and wherein the doped layer stacks do not overlie the source/drain regions, and wherein at least one of the doped layer stacks comprises the first conductivity type and at least one of the source/drain regions comprises a second, different conductivity type.

13. The capacitance of claim 12, wherein the first conductivity type comprises n-type and the second conductivity type comprises p-type.

14. The capacitance of claim 12, wherein the semiconductor body comprises a well of the first conductivity type within a substrate of the second conductivity type.

15. The capacitance of claim 12, wherein each of the plurality of doped layer stacks comprises an insulating layer and a polysilicon gate electrode overlying the insulating layer.

16. The capacitance of claim 12, further comprising an isolation region in the semiconductor body disposed between two of the plurality of source/drain regions.
